(19) United States
(12) Patent Application Publication
(10) Pub. No.: US 2016/0217976 A1
(43) Pub. Date: Jul. 28, 2016

(54) VACUUM PROCESSING APPARATUS

(71) Applicant: Hitachi High-Technologies Corporation, Tokyo (JP)

(72) Inventors: Takashi UEMURA, Tokyo (JP); Susumu TAUCHI, Tokyo (JP); Kohei SATO, Tokyo (JP); Eiji MARUYAMA, Tokyo (JP)

(73) Assignee: HITACHI HIGH-TECHNOLOGIES CORPORATION

(21) Appl. No.: 14/846,732

(22) Filed: Sep. 4, 2015

(30) Foreign Application Priority Data
Jan. 23, 2015 (JP) 2015-010807

(51) Int. Cl. H01J 37/32; C23C 16/44; C23C 16/50

(52) U.S. Cl. CPC H01J 37/3244; H01J 37/32009; C23C 16/50; C23C 16/4412; H01J 2237/334

(57) ABSTRACT

A vacuum processing apparatus with excellent processing uniformity and capable of effectively performing routine and non-routine maintenance even when an object to be processed has an increased diameter is provided. In the vacuum processing apparatus having a vacuum transfer chamber, this apparatus comprises a lower vessel having a cylindrical shape, a sample stage unit including a sample stage and a ring-shaped sample stage base having support beams disposed axisymmetric with respect to a central axis of the sample stage, an upper vessel having a cylindrical shape, and a moving mechanism which is fixed to the sample stage base and is capable to move the sample stage unit movable in a vertical direction and in a horizontal direction.

### BACKGROUND OF THE INVENTION

The present invention relates to a vacuum processing apparatus having one or more reduced-pressure processing chambers.

In a vacuum processing apparatus for performing processing of an object to be processed such as a semiconductor wafer, for example, a process gas is introduced into a vacuum processing chamber while it is in a reduced-pressure state, the introduced process gas is made into plasma, and the processing of the to-be-processed object such as a semiconductor wafer held on a sample stage having electrostatic chuck is performed by chemical reaction with radicals and/or ion sputtering.

Regarding the vacuum processing apparatus, its structure is disclosed, for example, in JP-A-2005-252201. An example of the electrostatic chuck used in the vacuum processing chamber is disclosed in JP-A-2005-516379.

### SUMMARY OF THE INVENTION

The vacuum processing apparatus uses a process gas and, in the event of processing an object to be processed (e.g., wafer) with the process gas made into plasma, reaction products adhere to the inside of the vacuum processing chamber. If the reaction products adhere to surfaces of parts disposed within the processing chamber, a problem occurs that the reaction products can peel off from the surfaces in the form of microparticles due to degradation of the parts to fall and attach onto the wafer or the like as foreign matters causing contamination. To suppress this, processings to remove reaction products or the like which become the source of foreign matters and/or to regenerate surfaces of respective parts (i.e. maintenance) by periodical replacement or cleaning of the parts within the processing chamber are performed. During maintenance, the processing chamber interior is exposed to an atmospheric pressure environment and no processing is executable so that the apparatus is deactivated, thereby resulting in a decrease in efficiency of the processing.

Furthermore, in recent years, semiconductor wafers which are objects to be processed become larger in diameter. Therefore, the vacuum processing apparatus also grows in size, resulting in tendency of increases in size as well as in weight of individual parts constituting it; detachment, transfer, and attachment of the parts would not easy and a time taken for maintenance is expected to become longer and a further decrease in maintenance efficiency is concerned.

In view of the foregoing, the inventors have studied the possibilities of an approach to solving the above-stated problems with the prior art. JP-A-2005-252201 discloses a vacuum processing apparatus having within an outside chamber an upper inside chamber which constitutes a processing chamber for performing the processing of an object to be processed, a sample stage, and a lower inside chamber disposed on the exhaust unit side. In this vacuum processing apparatus, during maintenance, a discharge chamber baseplate which is disposed above the upper inside chamber and which constitutes a discharge chamber that produces a plasma is lifted up as being rotated with a hinge portion disposed on the transfer chamber side as a supporting point so that a working space of the upper inside chamber is secured and thus the upper inside chamber is raised and taken out of the outside chamber. Further disclosed is a technique for lifting up a sample stage baseplate, to which is fixed a ring-shaped support base member (sample stage block) having support beams disposed and fixed around an axis with the center in the vertical direction of the sample stage as an axis in such a way as to rotate it with the hinge portion disposed on the transfer chamber side as a supporting point, to thereby secure the working space for the lower inside chamber and for lifting up the lower inside chamber to take it out of the outside chamber. Incidentally, by disposing the support beams in an axially symmetrical manner while letting the center in the vertical direction of the sample stage be the axis of symmetry (namely, the gas flow passage shape with respect to the center axis of the sample stage is almost coaxially symmetric), gases and the like (such as the process gas, and particles and reaction products in the plasma) in the space over the sample stage within the upper inside chamber pass through the space between these support beams and are exhausted via the lower inside chamber. Thereby, the gas flow in the circumferential direction of the object to be processed becomes uniform and uniform processing on the object to be processed is enabled.

When this technique for lifting up the discharge chamber baseplate and the sample stage baseplate with the hinge portions as supporting points to the maintenance of an object to be processed, which is enlarged in diameter, because the discharge baseplate and/or the support beams to which the sample stage is fixed become larger and their weights increase, it is concerned that it becomes difficult to lift them up by hand, thereby making it difficult to secure the working spaces of the upper inside chamber and the lower inside chamber. In addition, while the maintenance of the exhaust part is to be performed as being looked into from above the outside chamber, there is concern that it becomes difficult to carry out sufficient cleaning and other tasks because hands won't reach due to the increase in size of the apparatus. Moreover, it is concerned that non-routine maintenance such as servicing and replacement of the components constituting the lifted discharge baseplate and the sample stage may be performed on unstable foundations. Even if a crane or the like is used to lift up the discharge baseplate and/or the support beams to which the sample stage is fixed, two latter problems still remain unsolved.

JP-A-2005-516379 discloses a cantilevered substrate support which is capable to be attached to and detached from a vacuum processing chamber by passing it (in the horizontal direction) through an opening provided in the sidewall of the chamber and on which an electrostatic chuck assembly is mounted. In the case of applying this technique to the maintenance of an to-be-processed object which is increased in diameter, since the substrate support is vacuum-sealed at the opening in the sidewall of the chamber, it is concerned that holding the vacuum may become difficult as an increase in weight results in an increase in load applied to a vacuum seal portion. Also, it is likely that due to the cantilevered design the shape of a gas flow passage is not coaxially symmetrical with respect to the center axis of the sample-holding portion, resulting in a non-uniform gas flow in the circumferential direction of an object to be processed, thereby making it difficult to apply uniform processing to the to-be-processed object.

It is therefore an objective of this invention to provide a vacuum processing apparatus with excellent processing uniformity and capable of effectively performing not only routine maintenance but also non-routine maintenance even when an object to be processed increases in diameter.

As one mode for attaining the foregoing objective, a vacuum processing apparatus is provided, which includes a vacuum transfer chamber; a vacuum processing chamber which is connected to the vacuum transfer chamber, the vacuum processing chamber including: a baseplate which has a gas exhaust opening; a lower vessel which is disposed on the baseplate and has an inner wall a horizontal cross-section of which is circular; a sample stage unit which is disposed above the lower vessel and has a ring-shaped sample stage base, the ring-shaped sample stage base including: a sample stage on which an object to be processed is mounted; and support beams which support the sample stage and are disposed axisymmetric with respect to a central axis of the sample stage; an upper vessel which is disposed above the sample stage unit and has an inner wall a horizontal cross-section of which is circular; and a moving means which is fixed to the sample stage base and is capable to move the sample stage unit in a vertical direction and in a horizontal direction; a valve box which is disposed between the vacuum transfer chamber and the vacuum processing chamber, and is coupled to the baseplate; wherein the vacuum transfer chamber has a first opening through which the object to be processed is transferred to and from the vacuum processing chamber, and a first gate valve which opens and closes the first opening, wherein the vacuum processing chamber has a second opening through which the object to be processed is transferred to and from the vacuum transfer chamber, wherein the valve box connects the first opening and the second opening, and has a second gate valve which opens and closes the second opening.

According to this invention, it is possible to provide a vacuum processing apparatus with excellent processing uniformity and capable of effectively performing not only routine maintenance but also non-routine maintenance even when an object to be processed has an increased diameter.

Other objects, features, and advantages of the invention will become apparent from the following description of the embodiments of the invention taken in conjunction with the accompanying drawings.

### BRIEF DESCRIPTION OF THE DRAWINGS

FIG. 1A is a plan view illustrating a schematic construction of a vacuum processing apparatus in accordance with one embodiment of this invention;

FIG. 1B is a perspective view illustrating the schematic construction of the vacuum processing apparatus in accordance with the embodiment of this invention;

FIGS. 2A and 2B are schematic plan views of a principal part illustrating transfer of an object to be processed in the vacuum processing apparatus in accordance with the embodiment shown in FIGS. 1A and 1B;

FIG. 3 is a longitudinal cross-section schematically showing an outline of a structure of the vacuum processing chamber of the embodiment shown in FIGS. 1A and 1B;

FIG. 4 is a longitudinal cross-section schematically showing an outline of a structure of the vacuum processing chamber of the embodiment shown in FIGS. 1A and 1B;

FIG. 5A is a plan view for explanation of a maintenance procedure in a vacuum processing chamber of the vacuum processing apparatus in accordance with the embodiment of this invention shown in FIGS. 1A and 1B;

FIG. 5B is a longitudinal cross-section for explanation of a maintenance procedure in the vacuum processing chamber of the vacuum processing apparatus in accordance with the embodiment of this invention shown in FIGS. 1A and 1B;

FIG. 6A is a plan view for explanation of a maintenance procedure in a vacuum processing chamber of the vacuum processing apparatus in accordance with the embodiment of this invention shown in FIGS. 1A and 1B;

FIG. 6B is a longitudinal cross-section for explanation of a maintenance procedure in the vacuum processing chamber of the vacuum processing apparatus in accordance with the embodiment of this invention shown in FIGS. 1A and 1B;

FIG. 7A is a plan view for explanation of a maintenance procedure in a vacuum processing chamber of the vacuum processing apparatus in accordance with the embodiment of this invention shown in FIGS. 1A and 1B;

FIG. 7B is a longitudinal cross-section for explanation of a maintenance procedure in the vacuum processing chamber of the vacuum processing apparatus in accordance with the embodiment of this invention shown in FIGS. 1A and 1B;

FIG. 8A is a plan view for explanation of a maintenance procedure in a vacuum processing chamber of the vacuum processing apparatus in accordance with the embodiment of this invention shown in FIGS. 1A and 1B;

FIG. 8B is a longitudinal cross-section for explanation of a maintenance procedure in the vacuum processing chamber of the vacuum processing apparatus in accordance with the embodiment of this invention shown in FIGS. 1A and 1B;

FIG. 9A is a plan view for explanation of a maintenance procedure in a vacuum processing chamber of the vacuum processing apparatus in accordance with the embodiment of this invention shown in FIGS. 1A and 1B;

FIG. 9B is a longitudinal cross-section for explanation of a maintenance procedure in the vacuum processing chamber of the vacuum processing apparatus in accordance with the embodiment of this invention shown in FIGS. 1A and 1B;

FIG. 10A is a plan view for explanation of a maintenance procedure in a vacuum processing chamber of the vacuum processing apparatus in accordance with the embodiment of this invention shown in FIGS. 1A and 1B;

FIG. 10B is a longitudinal cross-section for explanation of a maintenance procedure in the vacuum processing chamber of the vacuum processing apparatus in accordance with the embodiment of this invention shown in FIGS. 1A and 1B;

FIG. 11A is a plan view for explanation of a maintenance procedure in a vacuum processing chamber of the vacuum processing apparatus in accordance with the embodiment of this invention shown in FIGS. 1A and 1B;

FIG. 11B is a longitudinal cross-section for explanation of a maintenance procedure in the vacuum processing chamber of the vacuum processing apparatus in accordance with the embodiment of this invention shown in FIGS. 1A and 1B;

FIG. 12 is a longitudinal cross-section schematically showing an outline of a structure of a vacuum processing chamber of a vacuum processing apparatus in accordance with a variation of the embodiment shown in FIGS. 1A and 1B; and

FIG. 13 is a longitudinal cross-section schematically showing an outline of a structure of a vacuum processing chamber of a vacuum processing apparatus in accordance with another variation of the embodiment shown in FIGS. 1A and 1B.

### DESCRIPTION OF THE EMBODIMENTS

To attain the foregoing objective, the inventors have conducted a study on methodology for satisfying three requirements below. Namely, (1) in order to secure excellent processing uniformity, the shape of a processing chamber is arranged to be substantially aligned and axially symmetric with respect to the center axis of a sample stage on which an object to be processed is mounted.

(2) In order to make easy routine maintenance possible, reaction products can be quickly removed from chamber members that are subject to routine maintenance even when it is coped with large diameters. Note here that easy routine maintenance involves eliminating the need for works to be performed in non-routine maintenance such as disconnecting power cables, performing purge of cooling-water line, etc. (3) In order to make easy non-routine maintenance possible, an electrode head for discharge and various types of sensors, which are subject to the non-routine maintenance, can be easily extracted even when it is coped with large diameters.

As a result, it was found that the following constructions would be effective.

For (1), at least an inner wall shape in the horizontal cross-section of a vacuum processing chamber is circular and beams supporting a sample stage are disposed axisymmetric with the center in the vertical direction of the sample stage being as the axis thereof and fixed to a ring-shaped support base member. For (2), parts subjected to routine maintenance are swappable. More specifically, instead of in-situ cleaning of parts to which reaction products adhere, they are made to be replaceable with new parts or cleaned ones. Furthermore, parts subjected to non-routine maintenance are integrated in units of relevant component groups and made to be movable in the horizontal direction on a per-unit basis to facilitate avoidance to ensure that they do not hinder routine maintenance operations. For (3), the units each consisting of a collection of relevant components subjected to the non-routine maintenance are moved in the horizontal direction on the occasion of maintenance, thereby providing a working space therearound.

Hereinafter, a description is given in accordance with an embodiment. It is noted that in the accompanying drawings, the same reference numerals are used to designate the same constituent elements.

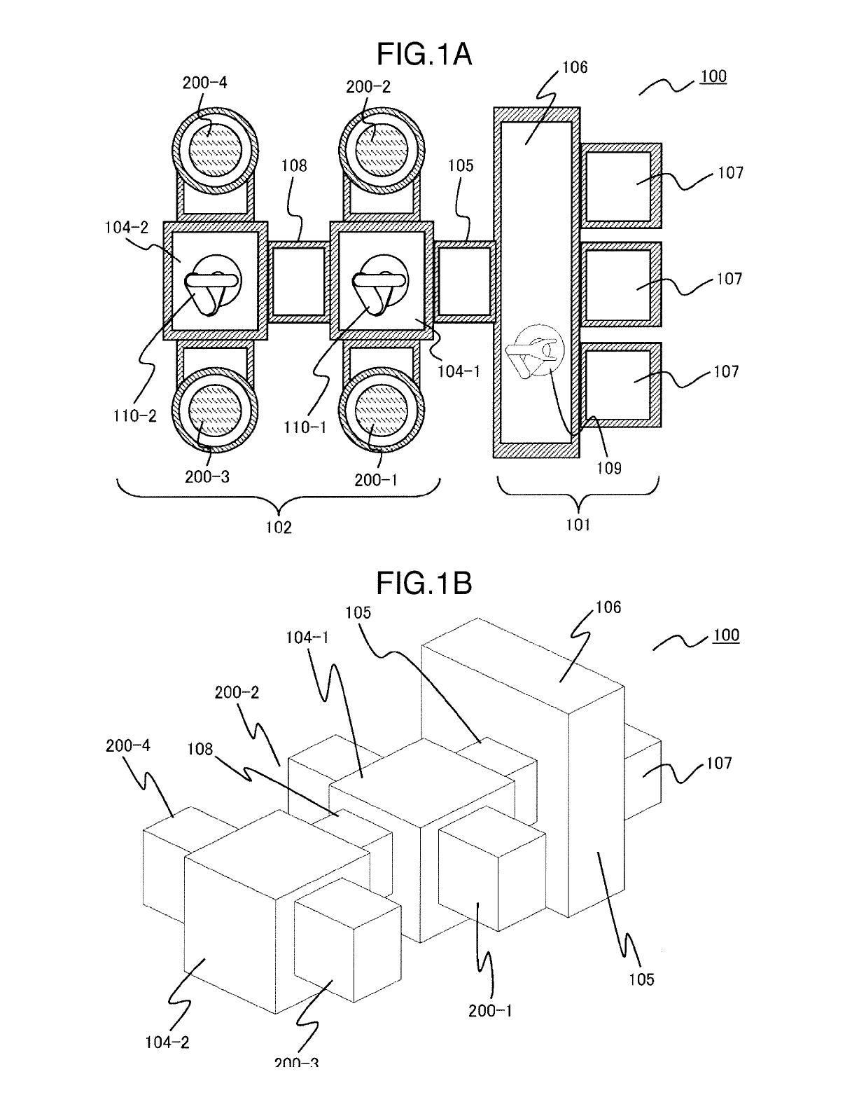

A vacuum processing apparatus in accordance with an embodiment of the present invention is described with reference to FIGS. 1A to 11. FIGS. 1A and 1B are a plan view and a perspective view illustrating a schematic construction of a vacuum processing apparatus in accordance with one embodiment of this invention, respectively. A plasma processing apparatus which is the vacuum processing apparatus 100 of this embodiment has an atmosphere block 101 and a vacuum block 102. The atmosphere block 101 is a part for performing under the atmospheric pressure transfer and determination of storage position of an object to be processed (sample) such as a semiconductor wafer, while the vacuum block 102 is a part for transferring and processing a sample such as a wafer at a reduced pressure from the atmospheric pressure and for increasing or decreasing the pressure in the state that the sample is mounted.

The atmosphere block 101 includes an atmosphere transfer chamber 106 and a plurality of cassette stages 107 which are attached to the front face side of this atmosphere transfer chamber 106 and on top surfaces of which cassettes that contain samples for processing/cleaning are placed. The atmosphere block 101 is a place where a wafer for processing/cleaning contained inside each of the cassettes on the cassette stages 107 is exchanged to and from the vacuum block 102, which is coupled to the back face of the atmosphere transfer chamber 106, and inside the atmosphere transfer chamber 106 an atmosphere transfer robot 109 having an arm to hold a wafer for such the wafer transfer is disposed.

The vacuum block 102 includes a plurality of vacuum processing chambers 200-1, 200-2, 200-3, 200-4 for performing sample processing under reduced pressure, vacuum transfer chambers 104-1, 104-2 coupled to these vacuum processing chambers and having vacuum transfer robots 110-1, 110-2 for performing therein sample transfer under reduced pressure, a lock chamber 105 which connects the vacuum transfer chamber 104-1 and the atmosphere transfer chamber 106 together, and a transfer intermediate chamber 108 that connects together the vacuum transfer chamber 104-1 and the vacuum transfer chamber 104-2. This vacuum block 102 is constituted from units having interior spaces which are reduced in pressure and capable of maintaining at the pressures of high degrees of vacuum. Control of operations of these atmosphere transfer robot and the vacuum transfer robots and of processing in the vacuum processing chambers are performed by a control device.

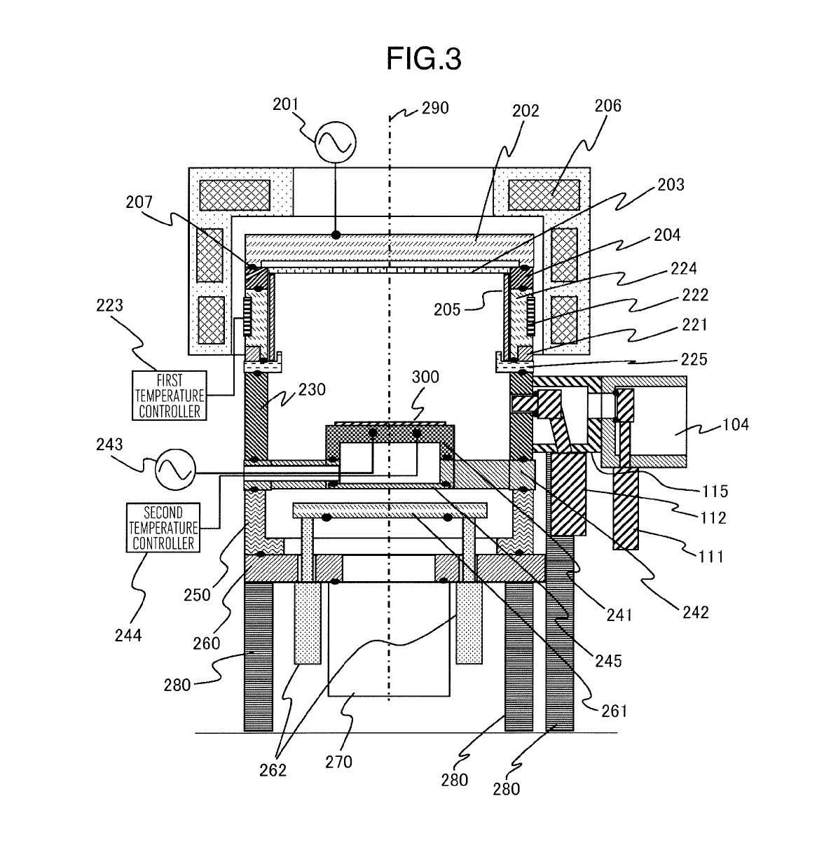

FIG. 3 is a longitudinal cross-section schematically showing an outline of a structure of one vacuum processing chamber of the embodiment shown in FIGS. 1A and 1B. Particularly, in FIG. 3, a construction of a vacuum processing chamber in the vacuum processing chamber 200 is schematically shown. Although in this embodiment vacuum processing chambers of the same structure are disposed, one or more vacuum processing chambers of different structures may be built therein.

The vacuum processing chamber shown in FIG. 3 has a vacuum vessel including an upper vessel 230 and a lower vessel 250, an underlying exhaust pump 270 coupled thereto, and a first radio-frequency (RF) power supply 201 and a solenoid coil 206 which overlie. The upper vessel and the lower vessel have inner walls each having a circular horizontal cross-sectional shape and, at their center inside, a sample stage 241 of a cylindrical shape is disposed. Outer walls of the upper vessel and the lower vessel constitute a vacuum partition. The sample stage 241 is held by support beams provided on a sample stage base 242 and the support beams are disposed axisymmetric with the center in the vertical direction of the sample stage as an axis (that is, the shape of a gas flow passage is substantially coaxially axisymmetric with respect to the center axis 290 of the sample stage). The gas and the like (the process gas and particles and reaction products in plasma) in the space over the sample stage 241 within the upper vessel 230 pass through spaces among these support beams are exhausted via the lower vessel 250 after having; thus, the gas flow in the circumferential direction of the sample stage 241 on which an object to be processed (sample) 300 becomes uniform, enabling execution of uniform processing to the object to be processed 300. Note here that the sample stage base 242 has a ring shape with support beams and that this ring part is held and vacuum-sealed around the lower vessel and the upper vessel constituting the vacuum vessel, thus making it possible to cope with any increase in weight of the sample stage or the like.

In this embodiment, the vacuum processing chamber is made up of a plurality of members sequentially stacked up on a baseplate 260, including the lower vessel 250 of the cylindrical shape, the ring-shaped sample stage base 242 having the support beams, the cylindrical upper vessel 230, an earth ring 225, a cylindrical discharge block 224, and a gas-introducing ring 204, respective members of which are vacuum-sealed with O-rings 207. Inside the discharge block 224 a cylinder-shaped quartz inner tube 205 is disposed. Additionally, the sample stage 241 having a sample stage bottom cover 245 is fixed to the sample stage base 242 to constitute a sample stage unit, while the discharge block 224 with a heater 222 attached thereto is fixed to a discharge block base 221 to constitute a discharge block unit. Also, the upper vessel 230, the lower vessel 250, and the baseplate 260 have flange portions, wherein the upper vessel 230 and the lower vessel 250 are secured with screws to the baseplate 260 at the corresponding flange portions, respectively. Although in this embodiment the members constituting the vacuum processing chamber have cylindrical shapes, with regard to their outer wall shapes, horizontal cross-section shapes may not be arranged to have circular shapes but to have rectangular or other cross-sectional shapes.

Above the vacuum processing chamber, there are disposed a cover member 202 having a disk shape for constituting the vacuum vessel and a disk-shaped shower plate 203 thereunder constituting a ceiling surface of the vacuum processing chamber. The cover member 202 and the shower plate 203 are dielectric components made of quartz or the like, which are arranged to enable RF electric field such as microwave, UHF wave, or VHF wave, to pass therethrough, and an electric field from the first RF power supply disposed above passes through them and is supplied to the inside of the vacuum processing chamber. In the outer circumference of an outside wall of the vacuum vessel, a magnetic field-creating means (solenoid coil) 206 is disposed so as to surround it so that it is arranged to supply a created magnetic field to the interior of the vacuum processing chamber.

In the shower plate 203, process gas introducing holes, which are a plurality of through holes, are arranged and a process gas introduced from the gas-introducing ring 204 are fed to the inside of the vacuum processing chamber through these introducing holes. As for the introducing holes of the shower plate 203 a plurality of the holes are disposed in an axisymmetric area around the center axis 290 of the sample stage 241 over a top surface of the sample stage 241 serving as a sample-mounting surface and process gas constituted from different gas components with a prescribed composition pass through the evenly disposed introducing holes are introduced into the vacuum processing chamber.

The process gas introduced into the vacuum processing chamber is excited by supplying an electromagnetic wave and a magnetic field which are generated by the first RF power supply 201 that is an electric field creation means and by the solenoid 206 that is a magnetic field creation means, and is made into plasma in the space inside of the discharge block 224 over the sample stage 241. At this time, molecules of the process gas are ionized into electrons and ions or dissociate into radicals. In the region in which this plasma is created, a heater 222, which is connected to a first temperature controller 223, is attached to able to heat the discharge block 224 that is provided as being disposed above the discharge block base 221 and the quartz inner tube 205 which is in contact with the plasma. With this arrangement, it is possible to reduce adhesion of reaction products to the quartz inner tube 205 and the discharge block 224. Thus, it is possible to exclude these members from the objects subjected to routine maintenance.

The sample stage 241 mounting a wafer thereon is disposed in the vacuum processing chamber in such a manner as to be aligned with the center axis 290 of the shower plate 203. When performing processing with plasma, the processing is performed while a wafer, which is an object to be processed 300, is placed on a circular mounting surface, which is the top surface of sample stage 241, and is adsorbed and held (electrostatically chucked) by film static electricity of the dielectric body constituting this surface. In this embodiment, the diameter of the cylindrical vacuum processing chamber is set to be 800 mm in view of the fact that the semiconductor wafer used here as a sample is 450 mm in diameter. However, it may alternatively be arranged to have other diameter values equal to or less than this size (e.g., 600 mm or more or less).

In addition, to electrodes disposed within the sample stage 241, an RF bias power supply (second RF power supply) 243 is connected; due to mutual reaction of the physical reaction caused by charged particles in the plasma being attracted to and colliding with the surface of the sample's surface by an RF bias formed over the sample stage 241 and sample 300 mounted thereon by supplying RF power thereto and chemical reaction between the radicals and the wafer surface, etch processing progresses. Also, the temperature of the sample stage is controllable to a desired temperature with a second temperature controller 244. Application of the RF bias to the sample stage 241 and the temperature control of the sample stage 241 are performed by way of power supply wirings and wirings for temperature control or piping for coolant which are disposed within a cavity formed in the sample stage base 242 including the support beams. Although not specifically depicted, it may also include, in addition to these wirings, wirings for a temperature sensor and an electrostatic chuck. The upper vessel 230 disposed at the periphery of the sample stage 241 is a member subjected to routine maintenance since reaction products readily attach thereto.

Below the vacuum processing chamber, the exhaust pump 270 is disposed which is coupled to its bottom portion via the baseplate 260 having an exhaust opening. This exhaust opening provided in the baseplate 260 is positioned straight below the sample stage 241 and the exhaust conductance can be adjusted by moving up and down an exhaust unit cover 261 having a substantially circular shape and being disposed above the exhaust opening by means of a cylinder 262, thereby performing adjustment of amounts and rates of internal gases, plasma, and reaction products to be discharged by the exhaust pump 270 to the outside of the vacuum processing chamber. During processing of the object to be processed, the exhaust unit cover 261 is, made open whereby the pressure of the interior space of vacuum processing chamber is maintained at a desired degree of vacuum due to balance between the supply of the process gas and the operation of the exhaust means such as the exhaust pump 270. In this embodiment, the pressure during processing is adjusted to a predefined value in a range of 0.1 to 4 Pa. A turbo-molecular pump is used as the exhaust pump. The exhaust unit cover 261 is closed during maintenance, thereby making it possible to vacuum-seal the exhaust pump with O-rings. Additionally, the reference numeral 111 designates a first gate valve, the numeral 112 indicates a second gate valve, the numeral 115 is a valve box, and the numeral 280 indicates support posts.

The process gas introduced into the vacuum processing chamber and the plasma and the reaction products produced during processing are forced, by an operation of the exhaust means such as the exhaust pump 270, to move from the upper part of the vacuum processing chamber through a space on the outer circumference side of the sample stage 241 and via the lower vessel 250 to the opening provided in the baseplate 260 below. As the reaction products easily attach to the lower vessel 250, it becomes a member subjected to routine maintenance.

An internal pressure of the vacuum processing chamber during etching processing is monitored with a vacuum gauge (not depicted) and controlled by controlling the exhaust velocity with the exhaust unit cover 261. The supply of the process gas and the operations of the electric field-forming means, the magnetic field-forming means, the RF bias, and the exhaust means are adjusted by a control device (not shown in the drawing) which is communicably connected thereto.

The process gas used for the plasma processing may be a single kind of gas or a mixed gas of a plurality of kinds of gases at appropriate flow ratios for each process condition. The mixed gas is adjusted in its flow rate by a gas flow rate controller (not depicted) and introduced through the gas-introducing ring 204 coupled thereto into a gas reservoir space between the cover member 202 and the shower plate 203 at the upper part of the vacuum processing chamber in the upper part of the vacuum vessel. In this embodiment the gas-introducing ring made of stainless steel is used.

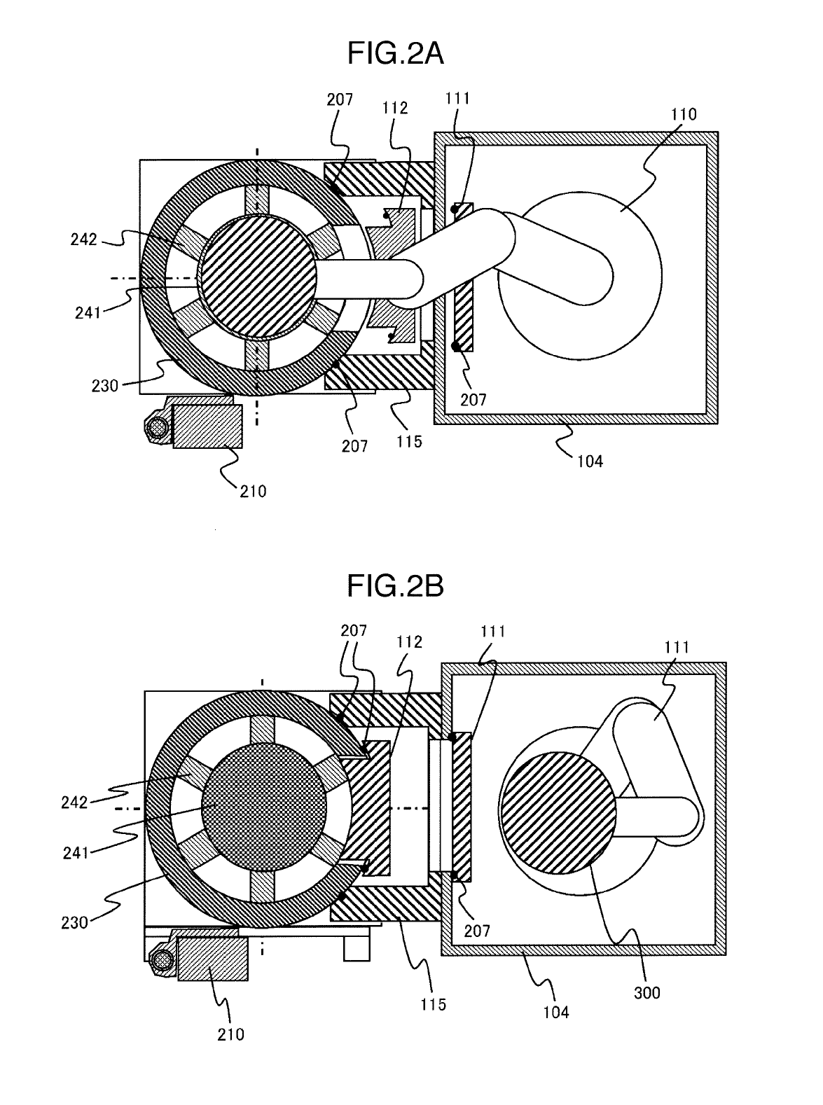

An explanation is given next on a procedure for loading an object to be processed into the vacuum processing chamber and unloading it from the chamber with reference to FIGS. 2A to 4. FIGS. 2A and 2B are schematic plan views of a principal part illustrating transfer of an object to be processed in the vacuum processing apparatus in accordance with the embodiment shown in FIGS. 1A and 1B. FIG. 2A depicts a state that the gate valve is opened, wherein the transfer robot is loading the to-be-processed object into the vacuum processing chamber or is unloading it therefrom. FIG. 2B shows a state that a wafer 300 has been loaded into the vacuum transfer chamber 104, wherein the gate valve is closed and the object to be processed has been loaded into the vacuum transfer chamber.

First, in the atmosphere block, a wafer that is taken out of a cassette by the atmosphere transfer robot is transferred to the vacuum transfer chamber 104 through the lock chamber. The vacuum processing chamber and the vacuum transfer chamber are connected together via the first gate valve 111 and the second gate valve 112. In the drawing, these gate valves are both closed and vacuum-sealed with O-rings 207. The reference numeral 115 designates the valve box and the numeral 210 is a turning lifter (moving means). Regarding the turning lifter 210, it is described later. Next, as shown in FIG. 2A, the vacuum transfer robot 110 having an arm is used to transfer a wafer 300 from the vacuum transfer chamber 104 to a vacuum processing chamber after the pressures of the vacuum processing chamber and the vacuum transfer chamber are made equal to each other. At this time, both of the first and the second gate valves 111 and 112 are in the open state. Next, as shown in FIG. 3, the vacuum transfer robot places the wafer 300 on the sample stage 241 in the vacuum processing chamber and returns to the vacuum transfer chamber; then, the first and the second gate valves 111, 112 are closed.

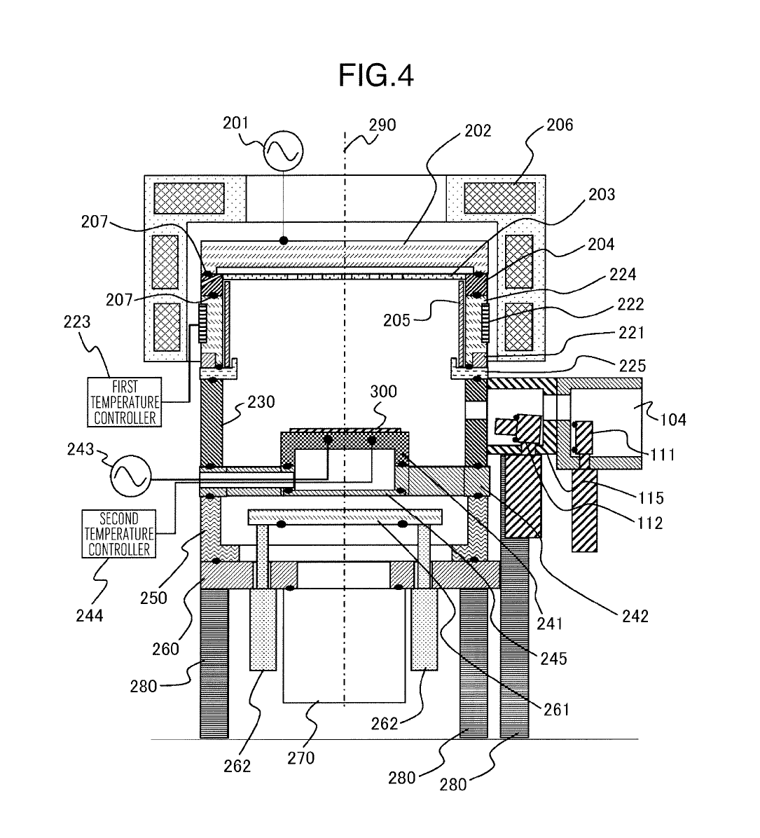

Once the processing applied to the wafer 300 is completed in the vacuum processing chamber, the pressures of the vacuum processing chamber and the vacuum transfer chamber are adjusted and, then, the first and the second gate valves 111, 112 are set to the open state as shown in FIG. 4. FIG. 4 is a longitudinal cross-section schematically showing an outline of the structure of the vacuum processing chamber of the embodiment shown in FIGS. 1A and 1B; this shows the state that the first and the second gate valves 111, 112 are both opened.

From this state, the wafer 300 is taken out of the sample stage 241 using the vacuum transfer robot 110 in a similar way to that shown in FIG. 2A. Consequently, as shown in FIG. 2B, the wafer 300 is transferred into the vacuum transfer chamber 104. Thereafter, the wafer 300 is sent to the cassette through the lock chamber after it has been processed in another vacuum processing chamber or no processing has been applied.

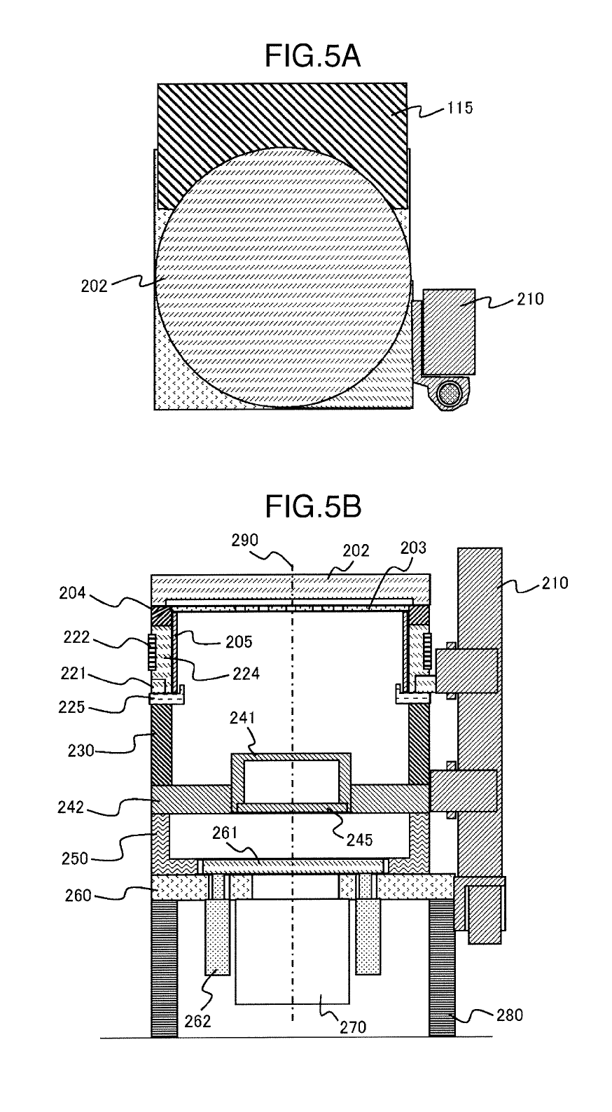

Next, a routine maintenance procedure is described using FIGS. 5A through 11B. FIGS. 5A and 5B show a structure obtained when the solenoid coil 206 and the first RF power supply 201 are removed from the vacuum processing chamber structure shown in FIGS. 3 and 4 and, further, the opening of the baseplate 260 connected to the exhaust pump 270 is closed with the exhaust unit cover 261 to thereby vacuum-seal it; FIG. 5A is a plan view and FIG. 5B is a longitudinal cross-section.

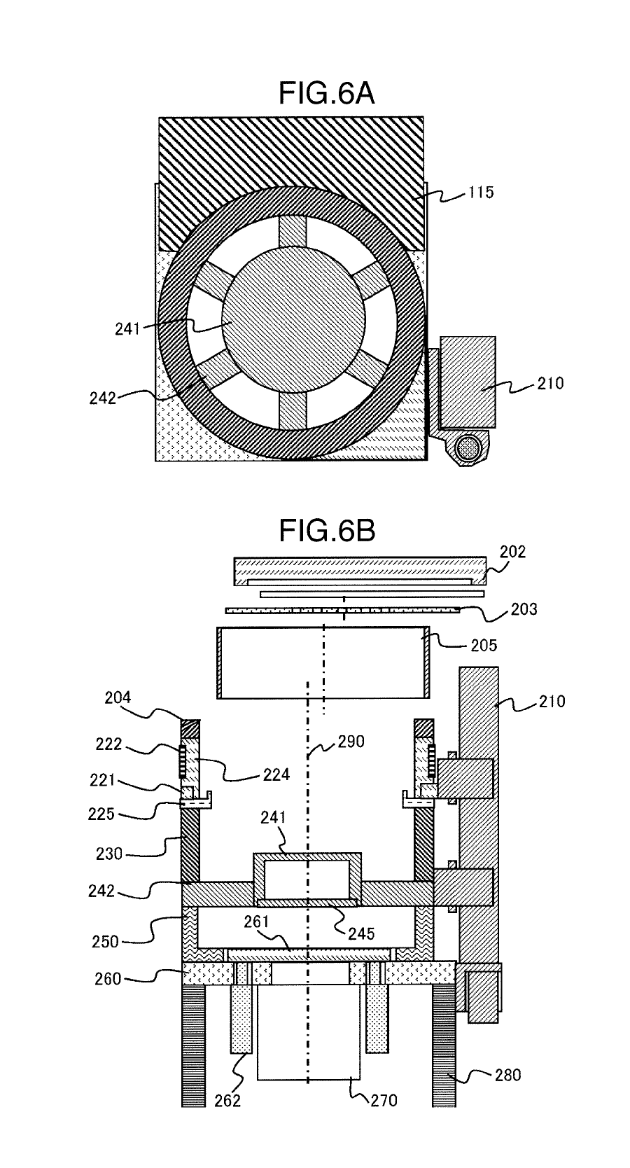

By vacuum-sealing the exhaust pump 270 with the exhaust unit cover 261 and leaving the exhaust pump 270 operate, it is possible to shorten a start-up time of the vacuum processing chamber after maintenance. Note here that the cross-section shown in FIG. 5B is viewed in a different direction from that of FIGS. 3 and 4 in order to describe the turning lifter 210. More specifically, while the cross-sections of FIGS. 3 and 4 are those viewed from the right in the plan view shown in FIG. 5A, the cross-section shown in FIG. 5B is that viewed from the bottom in the plan view shown in FIG. 5A. Longitudinal cross-sections of FIGS. 6B, 7B, 8B, 9B, 10B, and 11B are those viewed from the same direction as the cross-section shown in FIG. 5B.

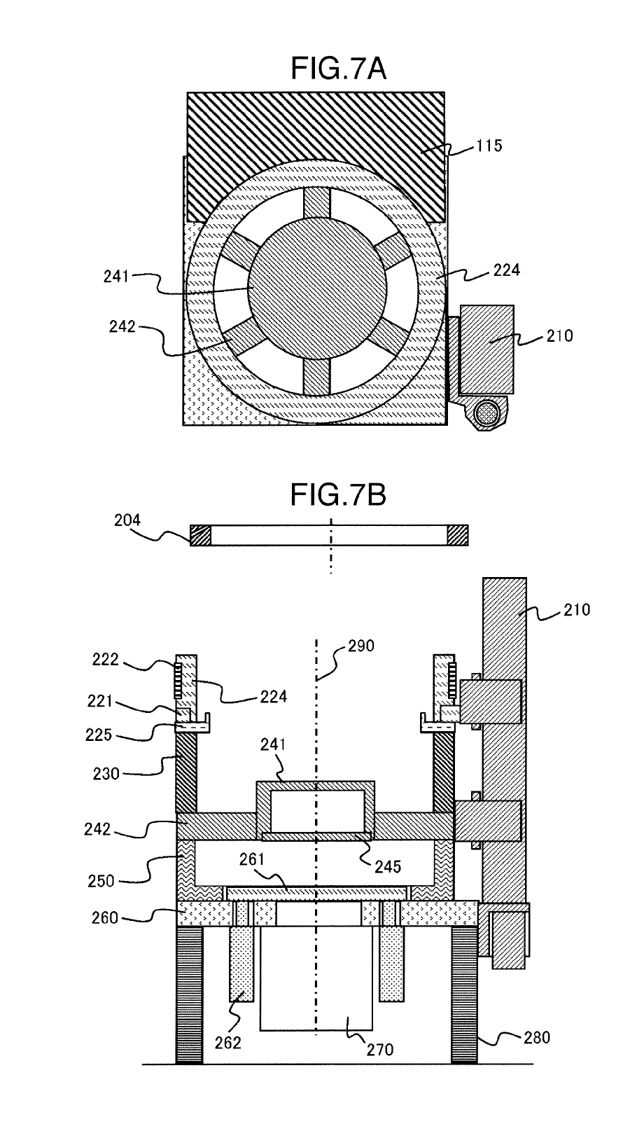

Next, as shown in FIGS. 6A and 6B, the quartz plate 202 and its underlying shower plate 203 and the quartz inner tube 205 are removed by moving them upward. This results in the situation that the gas-introducing ring 204 is exposed at the top end of the vacuum processing chamber. Additionally, in the interior of the vacuum processing chamber, the sample stage 241 and a part of the support beams of the sample stage base 242 are exposed. Then, as shown in FIGS. 7A and 7B, the gas-introducing ring 204 is taken away by moving it upward.

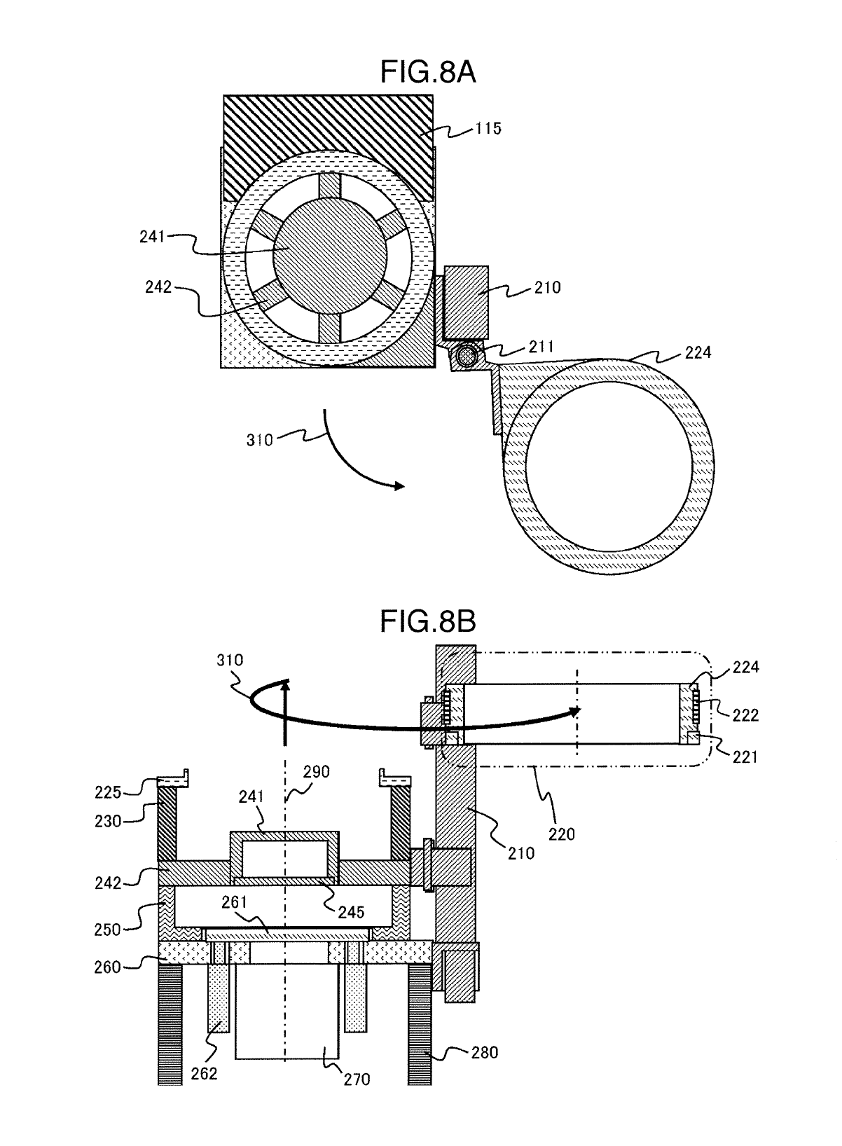

Sequentially, as shown in FIGS. 8A and 8B, a discharge block unit 220 which includes the discharge block base 221 fixed to a movable part of the turning lifter 210 and the discharge block 224 and the heater 222, which are attached thereabove, is moved upward and then pivoted horizontally in the counter-clockwise direction with a pivot shaft 211 as a center as indicated by an arrow 310, thereby moving to outside of the region of the vacuum processing chamber when viewed from vertically above. Although in this embodiment the discharge block unit is pivoted in the counter-clockwise direction, an alternative arrangement may also be employable which modifies the position of the turning lifter to the opposite side (the right-side layout in the figure is changed to the left-side layout) to thereby cause it to pivot in the clockwise direction.

A distance of the upward movement of the discharge block unit 220 is arranged to be equal to or greater than the height exceeding a projection of the earth ring 225. Although in this embodiment it is set to 5 cm, this invention should not be limited to this value. Meanwhile, in cases where the projection height of the earth ring is small, it is set to be equal to or greater than the height that allows the O-ring 207 to separate from the discharge block unit 220 or the earth ring 225 (a few centimeters). Additionally, while a pivot angle is set to 180 degrees, this angle may be any value 90 degrees or more and 270 degrees or less. Note, however, that an angle in the range of 180 degrees±20 degrees is preferable in light of the workability. By pivoting discharge-related members together which are not subjected to routine maintenance as the discharge block unit 220 in an all-at-once manner, it is possible to evacuate them rapidly and readily from over the vacuum processing chamber. By evacuating the discharge block unit 220, the earth ring 225 is exposed at the top end of the vacuum processing chamber.

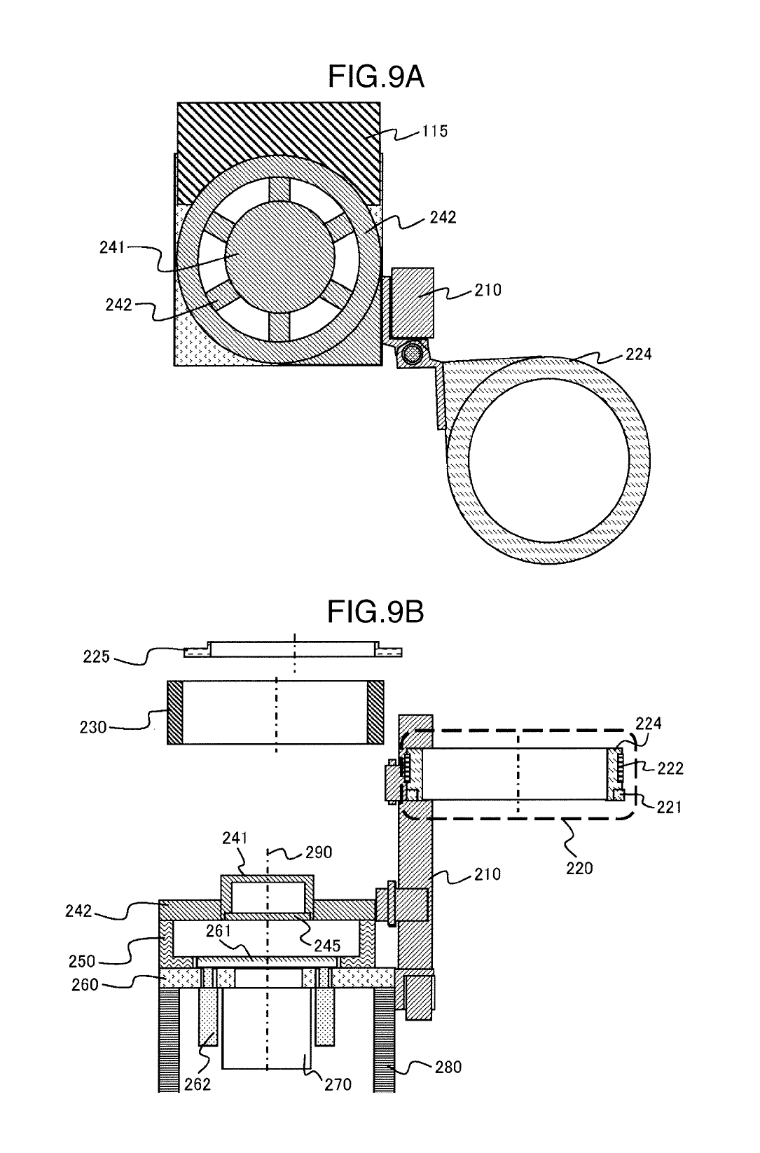

Next, as shown in FIGS. 9A and 9B, the earth ring 225 and the upper vessel 230, which is a primary member subjected to routine maintenance, are removed by moving them upward. Namely, it is possible to readily detach the upper vessel 230 in a swappable (replaceable) state.

In this embodiment, the vacuum partition (the upper vessel) per se, which constitutes the vacuum processing chamber, is replaceable. This makes it possible to minimize the time taken for maintenance of the upper vessel 230 after disassembly of the vacuum processing chamber.

Note here that, when the maintenance is performed, the first gate valve is closed whereas the second gate valve is opened. By closing the first gate valve 111 to set the vacuum transfer chamber 104 in the vacuum-sealed state, it becomes possible to perform processing in other vacuum processing chambers, thus making it possible to minimize degradation of the availability factor of the vacuum processing apparatus as a whole. On the other hand, by setting the second gate valve 112 in the open state, it is possible to separate the upper vessel 230 and the valve box 115 from each other.

The detachment of the upper vessel 230 is performed after removal of the screws which have secured the upper vessel 230 and the baseplate 260 together at the flange part. The movement of the discharge block unit is done by a control device which controls the turning lifter. This control device may be the one that is exclusively used for the turning lifter; alternatively, it may be built in the control device for an entirety of the vacuum processing apparatus as one part thereof. By removing the upper vessel 230, the ring part of the sample stage base 242 is exposed in addition to the sample stage 241 and the support beams.

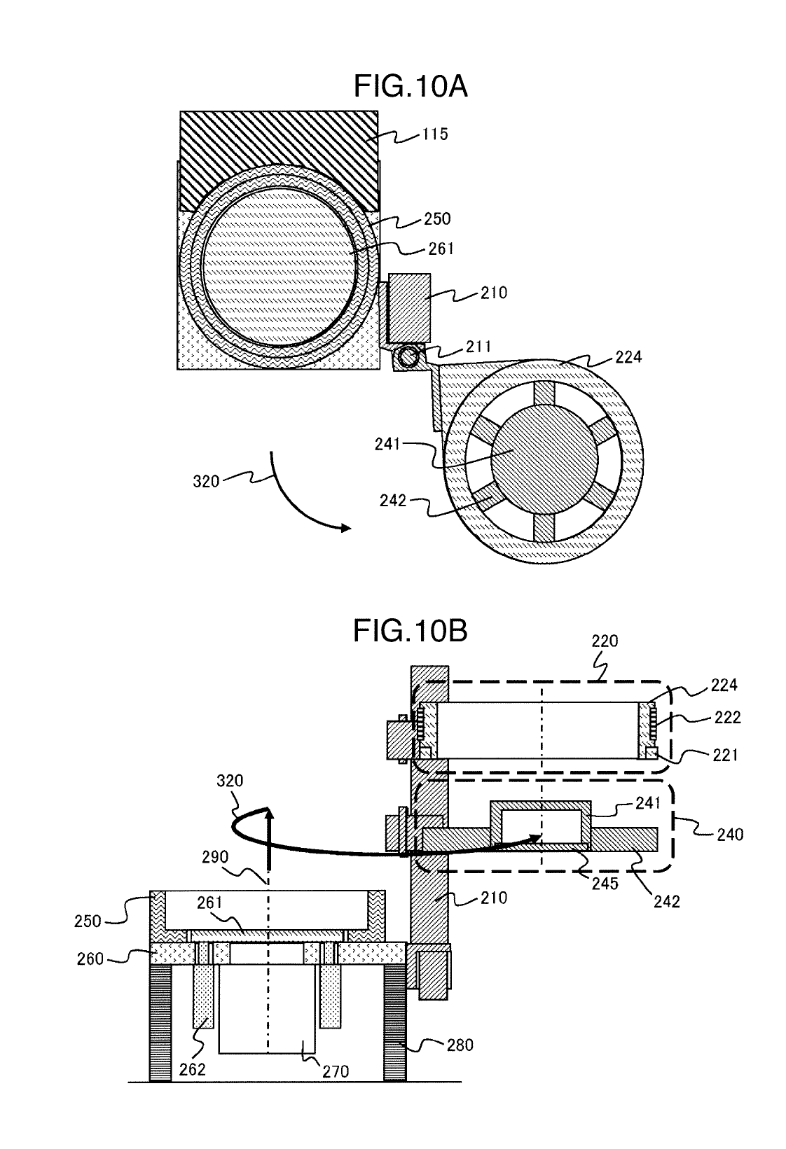

Next, as shown in FIGS. 10A and 10B, a sample stage unit 240 which includes the sample stage base 242 fixed to another movable part of the turning lifter 210 and the sample stage 241 and the sample stage bottom cover 245, which are attached thereabove, is moved upward and then horizontally pivoted in the counter-clockwise direction with the pivot shaft 211 as a center as indicated by an arrow 320, thereby moving to outside of the region of the vacuum processing chamber when viewed from vertically above. Although in this embodiment the sample stage unit is pivoted in the counter-clockwise direction, an alternative arrangement may also be employed which modifies the position of the turning lifter to the opposite side (the right-side layout in the figure is altered to the left-side layout) to thereby cause it to pivot in the clockwise direction.

A distance of the upward movement of the sample stage unit 240 is arranged to be equal to or greater than the height that allows the O-ring 207 to peel off from the sample stage unit 240 or the lower vessel 250. Although in this embodiment it is set to 2 cm, this invention is not limited thereto. Also, regarding the pivot angle, it is preferable to determine it to be the same as that of the discharge block unit 220. In this way, it is possible to make the total area of the discharge block unit 220 and the sample stage unit 240 small when viewed from vertically above.

By pivoting sample stage-related members together which are not subjected to routine maintenance as the sample stage unit 240 all at once, it is possible to evacuate them from over the vacuum processing chamber rapidly and readily. The movement of the sample stage unit 240 is performed by the control device that controls the turning lifter. This control device may be the one exclusively dedicated to the turning lifter; alternatively, it may be built in the control device for an entirety of the vacuum processing apparatus as one part thereof. By removing the sample stage unit 240, the lower vessel 250 is exposed at the top of the vacuum processing chamber. Also, the entire surface of the exhaust unit cover is exposed.

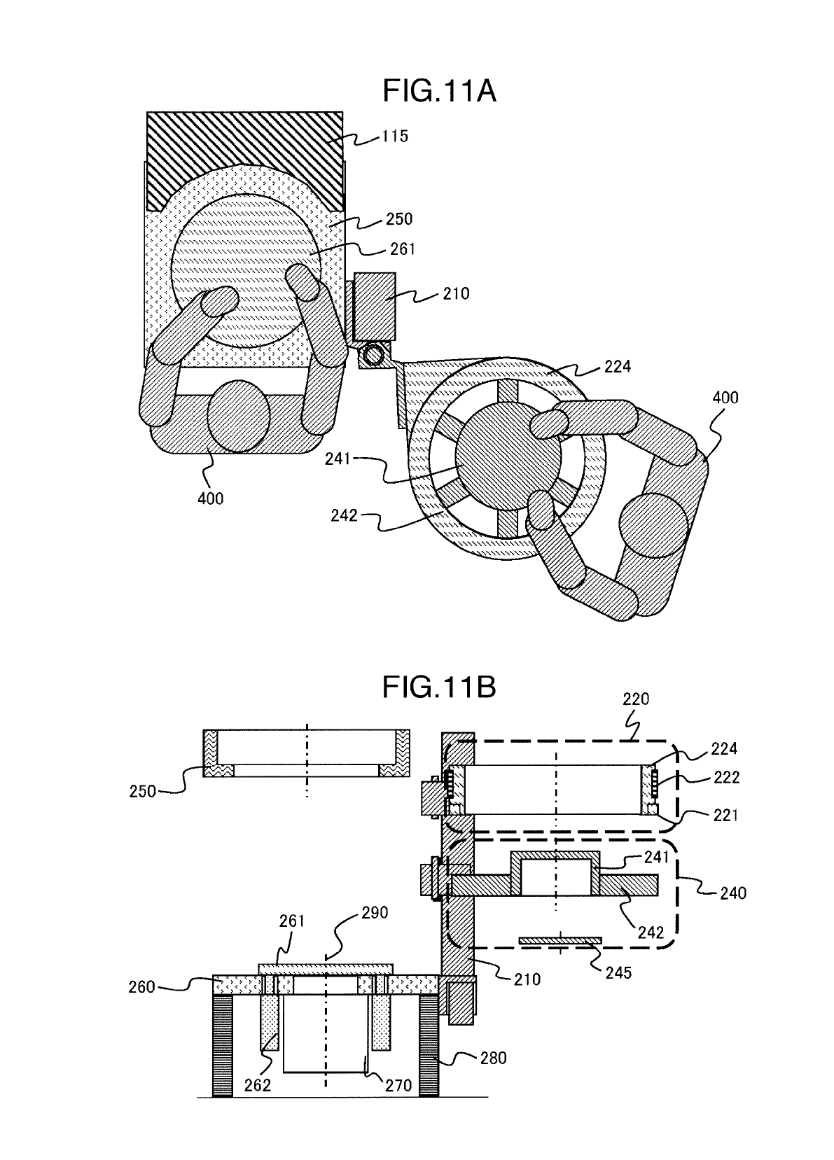

Subsequently, after removing the screws which secure the lower vessel 250 and the baseplate 260 together at the flange part, the lower vessel 250, which is a primary member subjected to routine maintenance, is moved upward to be removed as shown in FIGS. 11A and 11B.

Thus, it is possible to easily remove the lower vessel 250 in a swappable (replaceable) state. This makes it possible to minimize the maintenance time of the lower vessel 250 after disassembly of the vacuum processing chamber.

After having removed the lower vessel 250, inspection and servicing of surfaces of the baseplate 260 and the exhaust unit cover 261 are performed. Although the exposed portion of the baseplate 260 is covered with the lower vessel 250 so that the adhesion of the reaction products would be small and the upper surface of the exhaust unit cover 261 is positioned below the sample stage when the object to be processed is processed so that the adhesion of the reaction products would be small, cleaning may be performed to these members as needed. In the vicinity of the baseplate 260, walls making up the vacuum processing chamber or the like (an obstacle for maintenance) is absent and the construction is relatively flat; thus, it is possible to improve the maintenance working efficiency of workers 400 (shown in FIG. 11A).

After execution of cleaning of members subjected to routine maintenance, inspection/servicing, and replacement (especially, the upper vessel and the lower vessel), these are assembled in a procedure opposite to the above-stated for use in vacuum processing.

A non-routine maintenance procedure is described next. Members that are subjected to the non-routine maintenance are primarily parts constituting the discharge block unit 220 and parts constituting the sample stage unit 240.

In the case of the members constituting the discharge block unit 220, after the discharge block unit 220 is lifted up and pivoted in the horizontal direction as shown in FIGS. 8A and 8B, it is possible to perform from any desired directions maintenance tasks including inspection/replacement of the heater 222, inspection of the inner wall of the discharge block 224, and cleaning. As the discharge block unit 220 is evacuated away from other members making up the vacuum processing chamber, it is possible to improve the working efficiency.

In the case of the members constituting the sample stage unit 240, after the sample stage unit 240 is lifted up and pivoted in the horizontal direction as shown in FIGS. 10A and 10B, with the sample stage bottom cover 245 detached as shown in FIG. 11B, it is possible to perform from any desired directions maintenance of various types of power supply lines, wirings of sensors, and parts for temperature adjustment. Disposed in the cavity inside the support beams is at least one of a wiring used to adsorb electrostatically an object to be processed to the sample stage, a wiring used to apply the RF bias to the sample stage, a wiring or piping for coolant used to control the temperature of the sample stage, and a wiring used to detect the temperature of the sample stage, and these are also subjected to non-routine maintenance.

Note that in the case when the discharge block unit 220 hinders work operations, it is possible to pivot it back in the clockwise direction until it reaches the region where the vacuum processing chamber is disposed when viewed from vertically above or its proximity. This makes it possible to improve the working efficiency on the sample stage unit 240. It is also possible, by appropriately misaligning the pivot angles of the discharge block unit and the sample stage unit, to perform maintenance operations of the both units simultaneously, causing the working efficiency to improve accordingly.

Although in this embodiment the discharge block unit and the sample stage unit are lifted up and then pivoted in the horizontal direction, these may alternatively be arranged to be linearly pulled out in the horizontal direction after being lifted up. With this construction, it is possible to minimize the moving range. It is also possible to simplify the structure of a moving mechanism. Note, however, that pivot in the horizontal direction is deemed advantageous in securing the maintenance work space.

Although in this embodiment not only the upper vessel but also the lower vessel is replaced, another arrangement may be employed in which a linear (cover) is attached to cover the inner surface of the lower vessel and the linear is made replaceable.

Although this embodiment is arranged to use a single turning lifter for the discharge block unit and the sample stage unit to pivot in the same direction, a couple of turning lifters may be provided and pivoted in different directions respectively in cases where a working space is available. By separately providing one turning lifter for the discharge block unit and another for the sample stage unit, it is possible to freely set height of the respective units. In addition, since it is possible to allocate more workers, it becomes possible to readily perform many maintenance tasks simultaneously, thereby enabling completion of the work in a small amount of time, resulting in improvement of the working efficiency.

Also, even though in the above-stated embodiment those components other than the discharge block unit and the sample stage unit for which the turning lifter is used to move are moved by means of manpower, these may be moved by use of an equipment such as a crane.

Variations of the above-stated embodiment are now described with reference to some of the accompanying drawings. In the description below, those designated by the same reference numerals are the ones that are the same in the structure of the above embodiment and perform equivalent operations and functions; therefore, explanations thereof are eliminated unless otherwise needed particularly.

In the embodiment shown in FIGS. 3, 4, or the like, the baseplate 260 is fixed on the support posts 280, and it is constructed with the cylindrical lower vessel 250, the ring-shaped sample stage base 242 with the support beams, and the cylindrical upper vessel 230, which are stacked sequentially on the baseplate 260; the upper vessel 230 is coupled in contact with the valve box 115 fixed on the support posts 280 with the O-ring 207 laid therebetween, thereby sealing air-tightly between the inner space and the outside ambient air. Additionally, the discharge block base 222 and the sample stage base 242 which are lifted and pivoted at the time of maintenance are tied to the movable parts of the turning lifter 210, and the turning lifter 210 is coupled to the support posts 280 using bolts and screws.

Namely, the valve box 115 which is butted against the upper vessel 230 to seal air-tightly between its inner space and the outside ambient air while having a curved portion with the coinciding center axis 290 to come into contact with the outer wall of the upper vessel 230 having a cylindrical outer shape, the discharge block base 222, the upper vessel 230, and the sample stage base 242 are attached to the apparatus main body and, when their positions are fixed, since the support posts 280 are coupled and positioned in the layout of them to these components directly or with the baseplate 260 laid therebetween, the support posts 280 serve as a member which defines the reference for positioning.

When the valve box 115 and/or the turning lifter 210 due to malfunction or the like are replaced, maintenance tasks including such replacement are executable by separating respective ones from the support posts 280. In this example, the baseplate 260, the valve box 115, and the turning lifter 210 can be reattached to the support posts 280 in any given order of sequence.

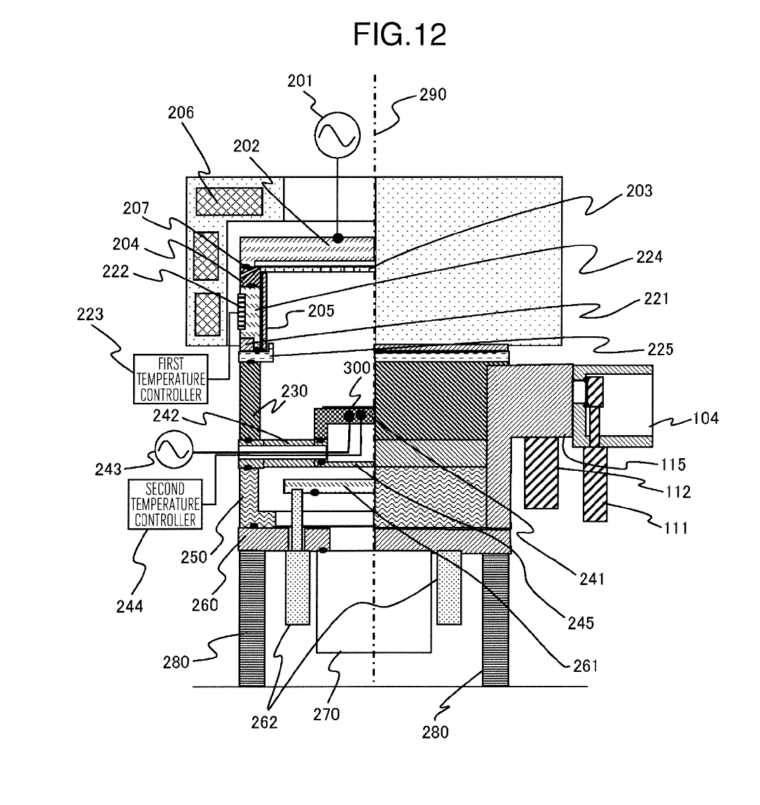

In a variation shown in FIG. 12, on the other hand, as a different structure from the embodiment, the baseplate 260 is coupled on the support posts 280 and positioned, a vacuum vessel is constructed with the cylindrical lower vessel 250, the ring-shaped sample stage base 242 with the support beams, and the cylindrical upper vessel 230, which are sequentially stacked above the baseplate 260, and the upper vessel 230 is butted and coupled via the O-ring 207 to the valve box 115, which is connected and fixed in position with bolts and screws to the baseplate 260 so that the inner space is air-tightly sealed from the outside ambient air. Furthermore, the turning lifter 210 is also connected with bolts and screws to the baseplate 260 similarly and the position is fixed.

Namely, the valve box 115 which is butted against the upper vessel 230 to seal air-tightly between its inner space and the outside ambient air while having a curved portion with the coinciding center axis 290 to come into contact with the outer wall of the upper vessel 230 having a cylindrical outer shape, the discharge block base 222, the upper vessel 230, and the sample stage base 242 are attached to the apparatus main body and, when their positions are fixed, since they are coupled and positioned with respect to the baseplate 260, the baseplate 260 serves as a member which defines the reference of their positions. In such the arrangement, in this example, the upper end of the support posts 280 and the baseplate 260 are coupled and fixed only themselves, thereby simplifying the structure including the support posts 280, and furthermore, management of attachment/mounting positions of the valve box 115, the discharge block base 222, the upper vessel 230, and the sample stage base 242 is simplified; as a result, it becomes easier to render the attachment tolerance of the parts of the apparatus to fall within allowable ranges, thereby achieving enhancement of assembly accuracy of the apparatus and improvement in working efficiency.

When the valve box 115 and/or the turning lifter 210 due to malfunction or the like are replaced, by detaching each from the baseplate 260, the coupling is released, thus enabling replacement thereof. Additionally, when either the second gate valve 112 or its driving means is replaced, since the coupling part of the second gate valve 112 and the valve box 115 is exposed to the outside of the apparatus, a worker readily gains an access to the coupling part between the valve box 115 and the upper vessel 230 or the baseplate 260, thereby facilitating replacement of the second gate valve 112. Note that, in this example, the order of fixing the positions is that, after the baseplate 260 is placed on the support posts 280 and fixed/coupled with respect to the support posts 280, the valve box 115 and the turning lifter 210 are attached to the baseplate 260.

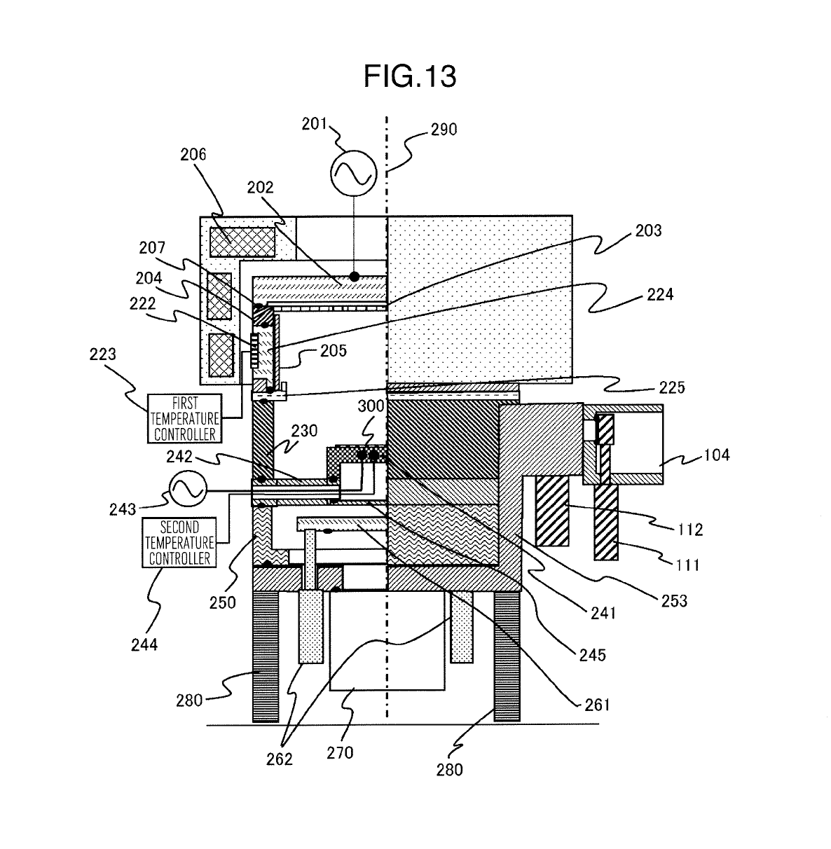

In a further variation shown in FIG. 13, as a structure different from the variation of FIG. 12, a valve box-added baseplate 253 which is formed with the valve box 115 and the baseplate 260 being integrated together is secured with screws and bolts to the top ends of the support posts 280 and positioned and on the valve box-added baseplate 253 the cylindrical lower vessel 250, the ring-like sample stage base 242 with the support beams, and the cylindrical upper vessel 230 are sequentially stacked to constitute the vacuum chamber.

In this structure, the cylindrical outer wall surface of the upper vessel 230 is coupled to and in contact with the valve box-added baseplate 253 with the O-ring 207 laid therebetween and the inside space and the outside ambient air are sealed air-tightly therebetween. Additionally, the turning lifter 210 is coupled to the valve box-added baseplate 253 and its position is fixed accordingly.

Namely, when mutual relative positions of the valve box-added baseplate 253, the discharge block base 222, the upper vessel 230, and the sample stage base 242 are fixed, it is the valve box-added baseplate 253 that defines the reference position therefor. More specifically, the valve box-added baseplate 253 is secured with screws and bolts to the top ends of the support posts 280 to fix their positions, and the discharge block base 222, the upper vessel 230, and the sample stage base 242 are connected to the valve box-added baseplate 253; these are not arranged to be directly connected to the support posts 280. Therefore, the structure of the support posts 280 may be simplified and it becomes easy to realize this with dimensions falling within their allowable tolerance.

Also, when the second gate valve 112 is replaced, the coupling part of the second gate valve 112 and the valve box-added baseplate 253 is exposed to a worker and, thus, it is easy to gain an access to the coupling part or the connecting portion between them, thereby facilitating execution of operation of part replacement, servicing, and inspection operations. Furthermore, by integrating the baseplate 260 and the valve box 115, although the structure becomes complex as a component per se, there are merits such as improvement of positioning accuracy for each part and reduction in the number of parts.

Although in the embodiment and the variations a vacuum processing apparatus of the electron cyclotron resonance (ECR) type is used as the vacuum processing apparatus, this is not to be construed as limiting the invention; the principles of this invention may also be applied to other types of apparatus, including those of the inductively-coupled plasma (ICP) type. Additionally, a vacuum processing apparatus having vacuum processing chambers disposed in the so-called link scheme is used; however, the invention is not limited thereto and is also applicable to those of the cluster scheme.

As has been stated above, in accordance with this invention, it is possible to provide a vacuum processing apparatus with excellent processing uniformity (coaxial axisymmetric evacuation) and capable of effectively performing not only routine maintenance but also non-routine maintenance even when an object to be processed is increased in diameter.

It should be noted that this invention should not be limited to the embodiment stated above and includes various modifications and alterations. For example, the above-stated embodiment is one that is set forth in detail in order to explain this invention in an way to understand easily, and this invention shall not be limited only to the one that has all of the constituent elements described. Part of a structure is replaceable with another structure, and a structure may also be added to another structure.

1. A vacuum processing apparatus comprising:
a vacuum transfer chamber;
a vacuum processing chamber which is connected to the vacuum transfer chamber, the vacuum processing chamber comprising:
a baseplate which has a gas exhaust opening;
a lower vessel which is disposed on the baseplate and has an inner wall a horizontal cross-section of which is circular;
a sample stage unit which is disposed above the lower vessel and has a ring-shaped sample stage base, the ring-shaped sample stage base comprising:
a sample stage on which an object to be processed is mounted; and
support beams which support the sample stage and are disposed axisymmetric with respect to a central axis of the sample stage;
an upper vessel which is disposed above the sample stage unit and has an inner wall a horizontal cross-section of which is circular; and
a moving means which is fixed to the sample stage base and is capable to move the sample stage unit in a vertical direction and in a horizontal direction; and
a valve box which is disposed between the vacuum transfer chamber and the vacuum processing chamber, and is coupled to the baseplate;
wherein the vacuum transfer chamber has a first opening through which the object to be processed is transferred to and from the vacuum processing chamber, and a first gate valve which opens and closes the first opening,
wherein the vacuum processing chamber has a second opening through which the object to be processed is transferred to and from the vacuum transfer chamber,
wherein the valve box connects the first opening and the second opening, and has a second gate valve which opens and closes the second opening.

2. The vacuum processing apparatus according to claim 1, wherein the gas exhaust opening of the baseplate is disposed directly beneath the sample stage.

3. The vacuum processing apparatus according to claim 1, wherein couplings between the baseplate and the lower vessel, between the lower vessel and the sample stage unit, and between the sample stage unit and the upper vessel are vacuum-sealed respectively.

4. The vacuum processing apparatus according to claim 1, wherein during maintenance of the vacuum processing apparatus, the first gate valve is set in a closed state and the second gate valve is set in an open state.

5. The vacuum processing apparatus according to claim 1, wherein the sample stage unit is configured to be lifted up by the moving means and then to be pivoted horizontally.

6. The vacuum processing apparatus according to claim 1, wherein during maintenance of the vacuum processing apparatus, the upper vessel and the lower vessel are replaced.

7. The vacuum processing apparatus according to claim 1, wherein during maintenance of the vacuum processing apparatus, the upper vessel and the lower vessel are replaced.

8. The vacuum processing apparatus according to claim 1,
wherein the lower vessel has a liner therein,
wherein during maintenance of the vacuum processing apparatus the liner of the lower vessel and the upper vessel are replaced.

9. The vacuum processing apparatus according to claim 1, wherein the gas exhaust opening of the baseplate is set in an open state during operation of the vacuum processing apparatus and is set in a closed state during maintenance of the vacuum processing apparatus.

10. The vacuum processing apparatus according to claim 1, wherein at least one of the support beams comprises a cavity therein;
wherein at least one of a wiring used to electrostatically adsorb the object to be processed to the sample stage, a wiring used to apply a radio-frequency bias to the sample stage, a wiring or piping for coolant used to control a temperature of the sample stage, and a wiring used to detect a temperature of the sample stage is disposed in the cavity.
